(19) United States
(12) Patent Application Publication
(10) Pub. No.: US 2016/0147599 A1
(43) Pub. Date: May 26, 2016

(54) Memory Systems that Perform Rewrites of Resistive Memory Elements and Rewrite Methods for Memory Systems Including Resistive Memory Elements

(71) Applicant: Daeshik Kim, Hwaseong-si (KR)

(72) Inventor: Daeshik Kim, Hwaseong-si (KR)

(21) Appl. No.: 14/814,076

(22) Filed: Jul. 30, 2015

(30) Foreign Application Priority Data
Nov. 25, 2014 (KR) 10-2014-0165384

(51) Int. Cl. G06F 11/10; G06F 3/06; G11C 29/52

(52) U.S. Cl. CPC G06F 11/1068; G11C 29/52; G06F 3/0619; G06F 3/064; G06F 3/0679

(57) ABSTRACT

A method of operating a nonvolatile memory device, such as a resistive memory device. The method includes performing error correction code (ECC) processing on data read from resistive memory cells to detect whether any of the resistive memories or soft error cell; checking completion of a read operation after storing an address of the soft error cell when the soft error cell is detected; and selectively rewriting error-corrected data into a soft error cell corresponding to the stored address in response to determining that the read operation is completed.

### CROSS-REFERENCE TO RELATED APPLICATIONS

This US non-provisional patent application claims priority under 35 USC §119 to Korean Patent Application No. 10-2014-0165384, filed on Nov. 25, 2014, the disclosure of which is incorporated by reference in its entirety herein.

### BACKGROUND

1. Technical Field

Embodiments of the present disclosure relate to memory systems including nonvolatile memory devices and, more particularly, to memory systems including resistive memory elements.

2. Discussion of Related Art

In general, semiconductor memory devices may be classified as volatile memory devices, such as DRAM and SRAM devices, and nonvolatile memory devices, such as EEPROM, FRAM, PRAM, MRAM, and flash memory devices.

Volatile memory devices lose their stored data when power to the devices is interrupted. Volatile memory devices include a static RAM (SRAM), a dynamic RAM (DRAM), a synchronous DRAM (SDRAM), and the like. In contrast, nonvolatile memory devices may retain their stored data even when power to the devices is interrupted. Nonvolatile memory devices include a read only memory (ROM), a programmable ROM (PROM), an electrically programmable ROM (EPROM), an electrically erasable and programmable ROM (EEPROM), a flash memory, a phase-change RAM (PRAM), a resistive RAM (ReRAM), a ferroelectric RAM (FRAM), and the like.

In particular, MRAM, PRAM, and ReRAM devices are often called resistive memories because data is stored in the memory cells according to a high-resistance or low-resistance state of the memory cell.

### SUMMARY OF THE INVENTION

The present disclosure provides a memory system for improving a raw bit error rate of a nonvolatile memory device and a write method of the nonvolatile memory device.

A method of operating a nonvolatile memory device according to some embodiments of the inventive concept may include performing error correction code (ECC) processing on data read from resistive memory cells to detect whether the resistive memory cells include a soft error cell that experiences a soft error and to generate error-corrected data for the soft error cell, storing an address of the soft error cell in response to detecting the soft error cell, and selectively rewriting the error-corrected data into the soft error cell corresponding to the stored address.

In example embodiments, the resistive memory cells may be MRAM cells.

In example embodiments, each of the MRAM cells may include a magnetic tunnel junction (MTJ) element.

In example embodiments, the soft error cell may be an error cell created by a read error rate.

In example embodiments, the write may be performed in each set period.

In example embodiments, the error correction code (ECC) processing may be performed to correct one bit of error.

In example embodiments, the method may further include performing a read verify operation to verify whether the rewrite is successfully performed.

In example embodiments, selectively rewriting the error-corrected data may be performed in response to a raw bit error rate of the resistive memory cells exceeding a predetermined bit error rate.

In example embodiments, the nonvolatile memory device may be mounted on a timing controller as a data storage device.

In example embodiments, the timing controller may control a display circuit block in a display device.

In some embodiments, the method may further include checking completion of a read operation after storing the address of the soft error cell. In some embodiments, selectively rewriting the error-corrected data is performed after the read operation has completed.

A method of operating a nonvolatile memory device according to another embodiment of the inventive concept may include writing data into resistive memory cells, reading the data written into the resistive memory cells after writing the data into the resistive memory cells, performing error correction code (ECC) processing on data read from the read data to detect whether there is a soft error cell and to generate error-corrected data for the soft error cell, and selectively rewriting the error-corrected data into the soft error cell when the soft error cell is detected.

In example embodiments, the resistive memory cells may be STT-MRAM cells.

A memory system according to an embodiment of the inventive concept may include a resistive memory device including a memory cell array including a plurality of memory cells; and a memory controller including an ECC engine configured to perform an error correction code (ECC) processing and a rewrite managing unit configured to selectively rewrite error-corrected data into a soft error cell through the ECC processing when there is the soft error cell among the memory cells.

According to embodiments of the inventive concepts, characteristics of a read error rate that a memory cell requires are relaxed. Thus, a raw bit error rate of a nonvolatile memory device is improved to guarantee reliability of a memory system including the nonvolatile memory device.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain principles of the disclosure. In the drawings:

FIG. 1 is a block diagram of a memory system according to an embodiment of the inventive concept;

FIG. 2 is a block diagram of a memory device shown in FIG. 1;

FIG. 3 is an exemplary detailed block diagram of a memory cell array in FIG. 2;

FIG. 4 is another exemplary detailed block diagram of a memory cell array in FIG. 2;

FIG. 5 is an exemplary diagram illustrating a configuration of a memory cell in a memory cell array in FIG. 2;

FIGS. 6 and 7 illustrate magnetization directions of a variable resistance memory according to stored data;

FIG. 8 illustrates a write operation of an STT-MRAM;

FIGS. 9 and 10 illustrate embodiments of a variable resistance memory in an ST-MRAM;

FIG. 11 illustrates another embodiment of a variable resistance memory in an SIT-MRAM;

FIGS. 12 and 13 illustrate another embodiment of a variable resistance memory in an STT-MRAM;

FIG. 14 is a detailed block diagram illustrating an exemplary configuration of a controller in FIG. 1;

FIG. 15 is a rewrite control flowchart during a read operation;

FIG. 16 is a write control flowchart during a write operation;

FIG. 17 is a block diagram of a memory system according to another embodiment of the inventive concept;

FIG. 18 is a block diagram of a nonvolatile memory system with a multi-channels structure according to another embodiment of the inventive concept; and

FIG. 19 is a block diagram of an electronic device including the nonvolatile memory system in FIG. 18.

### DETAILED DESCRIPTION

Example embodiments of the present disclosure will now be described more fully through the following exemplary embodiments related to the accompanying drawings. However, the disclosure is not limited to the following embodiments but may be embodied in other forms.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements. Other words used to describe relationships between elements should be interpreted in a like fashion (i.e., “between” versus “directly between,” “adjacent” versus “directly adjacent,” etc.).

Moreover, the same or like reference numerals in each of the drawings represent the same or like components if possible. In some drawings, the connection of elements and lines is just represented to effectively explain technical content and may further include other elements or circuit blocks.

Note that each embodiment that is herein explained and exemplified may also include its complementary embodiment and the details of basic data access operations to a MRAM and internal function circuits not described in order not to make the subject matter of the disclosure ambiguous.

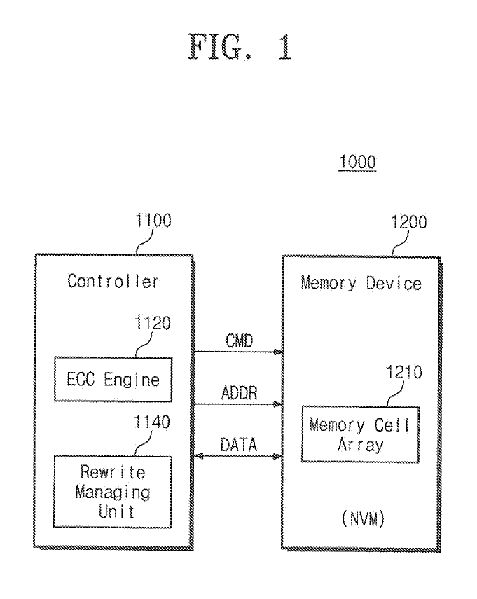

FIG. 1 is a block diagram of a memory system 1000 according to some embodiments of the inventive concept. As illustrated, the memory system 1000 includes a controller 1100 that functions as a memory controller and a memory device 1200 whose operation is controlled by the controller 1100.

The memory device 1200 may be a nonvolatile memory, such as a resistive memory. The memory device 1200 may be controlled by the controller 1100 and may perform operations (e.g., read or write operations) requested by the controller 1100.

The controller 1100 includes an ECC engine 1120 and a rewrite managing unit 1140. The ECC engine 1120 performs error correction code (hereinafter referred to as “ECC”) processing. The rewrite managing unit 1140 controls a rewrite operation. According to some embodiments, the rewrite managing unit 1140 selectively rewrites error-corrected data into a soft error cell through the ECC processing when there is the soft error cell among a plurality of memory cells in a memory cell array 1210.

The term “soft error cell” means a memory cell that is experiencing a soft error in which written data is frequently read incorrectly during a read operation. When a certain memory cell is a soft error cell, a memory cell into which data “1” is written may be frequently read as data “0” while a memory cell into which data “0” is written may be frequently read as data “1”. In case of a resistive memory, write current applied to a memory cell is greater than read current. However, there is probability that data can be written into a memory cell even by a read current, which is called a read error rate. One of the ways to reduce the read error rate is to increase height of a thermal barrier of a magnetic tunnel junction (MTJ) constituting a memory cell of a resistive memory. However, this means that the write current needed to write data to the memory cell during a write operation must be increased. Increasing the write current causes the power consumption during the write operation to increase. Since a soft error cell may be generated by a read current, characteristics of a raw bit error rate that a memory cell must have need to be relaxed by reducing the read error rate.

In some embodiments of the inventive concept, a rewrite may be performed after a read operation or a write operation.

In case of a read operation, the memory system 1000 performs ECC processing on data read from resistive memory cells to detect whether there is a soft error cell in the memory cells from which data has been read. When a soft error cell is detected, the address of the soft error cell is stored. In some embodiments, error corrected data corresponding to the soft error cell is also stored. The memory system 1000 then checks to see if the entire read operation is complete. If the read operation is complete, error-corrected data is selectively written into a soft error cell corresponding to the stored address. Multiple soft error cells among the memory cells can be corrected in this manner.

In case of a write operation, the memory system 1000 reads data written into resistive memory cells after writing the data into the resistive memory cells. The memory system 1000 performs ECC processing on data read from the read data to detect whether there is a soft error cell in the memory cells to which data has been written. If a soft error cell is detected, error-corrected data is selectively written into the soft error cell. Multiple soft error cells among the memory cells can be corrected in this manner.

The controller 1100 may be connected to a host. The controller 1100 may provide a command CMD, an address ADDR, and data DATA to the memory device 1200 to control read and write operations on the memory device 1200 in response to a request of the host.

In some example embodiments, when a write operation is performed, the controller 1100 may provide a write command and write-requested data to the memory device 1200. At this point, the controller 1100 may also provide an address corresponding to the write-requested data to the memory device 1200.

In other example embodiments, when a read operation is performed, the controller 1100 may provide a read command and an address corresponding to a read-requested area to the memory device 1200.

In some example embodiments, the controller 1100 may be implemented to be similar to a DRAM controller, and may exchange signals and/or data with the memory device 1200 through a DRAM interface.

In some embodiments of the inventive concept, the rewrite may be executed at least once within regularly set periods. For example, the rewrite operation may be performed within a rewrite period that occurs once per second. The rewrite operation may be executed in regular time intervals and/or after read operations and/or write operations.

One or two bits of error in a data word may be corrected by ECC processing, and selection of rewrite on a soft error cell may be decided according to a raw bit error rate. For example, although a memory cell is a soft error cell, rewrite may not be unconditionally executed. A raw bit error rate of a memory may be managed based on a number of read accesses, and a rewrite operation may be performed on a soft error cell when the raw bit error rate of the memory is greater than a predetermined rate.

In some embodiments of the inventive concept, a nonvolatile memory device may be mounted on a timing controller in a display device as a data storage element instead of an SRAM.

The timing controller serves to control a display circuit block in the display device.

According to such a memory system as shown in FIG. 1, read error rate characteristics requested for a memory cell are relaxed to improve a raw bit error rate of a nonvolatile memory device. Thus, reliability of the memory system including the nonvolatile memory may be improved.

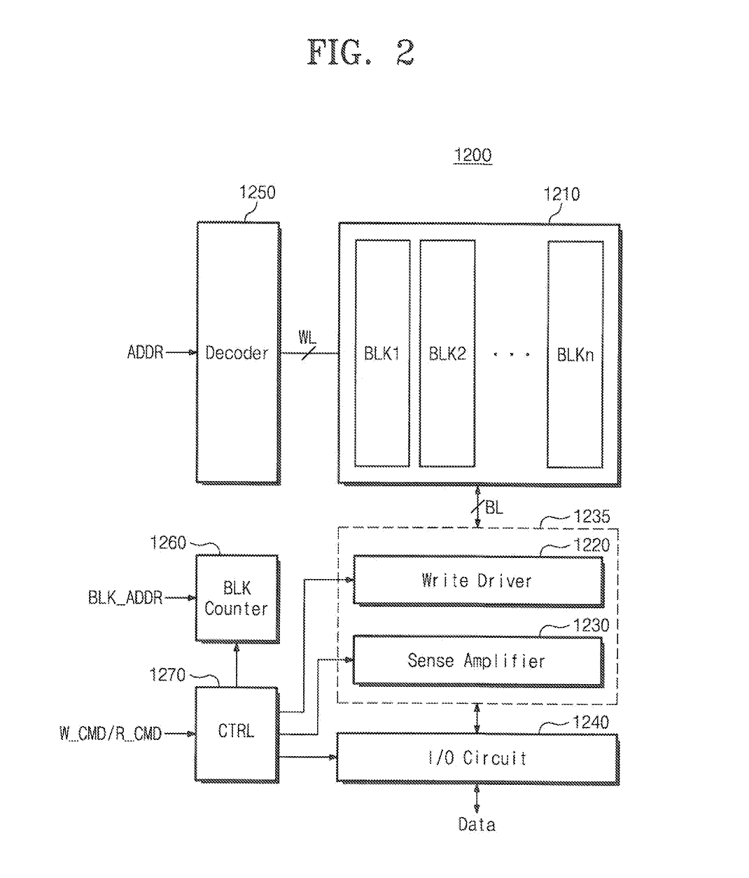

FIG. 2 is a block diagram of the memory device 1200 shown in FIG. 1. For brevity of description, a case of implementing the memory device 1200 with a single memory chip is illustrated in FIG. 2.

As illustrated in FIG. 2, the memory device 1200 may include a memory cell array 1210, a write driver 1220, a sense amplifier 1230, an input/output (I/O) circuit 1240, a decoder 1250, a block counter 1260, and a control logic 1270. The write driver 1220 and the sense amplifier 1230 may be referred to as a write and sense circuit 1235.

The memory cell array 1210 is connected to the decoder 1250 through a plurality of wordlines WL. The memory cell array 1210 is connected to the write and sense circuit 1235 through a plurality of bitlines BL. The memory cell array 1210 includes a plurality of blocks BLK1 to BLKn each including a plurality of memory cells to store data.

In embodiments of the inventive concept, the memory cell array 1210 may be implemented using a variable resistance memory as a nonvolatile memory. For example, memory cells of the memory cell array may be implemented with spin transfer magnetoresistive random access memory (hereinafter referred to as “STT-MRAM”) cells.

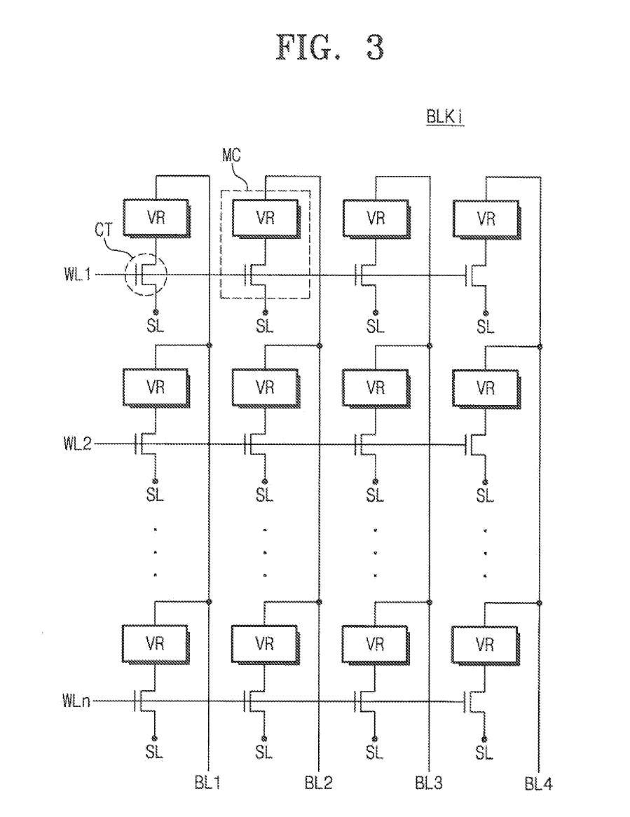

When the memory cells are implemented with STT-MRAM cells, each of the memory cells may include a magnetic tunnel junction element (hereinafter referred to as “variable resistance element”) having a magnetic material. Examples of implementing the memory cell array 1210 and the memory cell will be described in further detail later with reference to FIGS. 3 to 5.

The write driver 1220 is connected to the memory cell array 1210 through a bitline BL. The write driver 1220 provides write current corresponding to write-requested data to the memory cell array 1210 through the bitline BL during a write operation. The write driver 1220 provides read current to the memory cell array 1210 through the bitline BL during a read operation.

The sense amplifier 1230 is connected to the memory cell array 1210 through the bitline BL. The sense amplifier 1230 receives a data voltage through the bitline BL and amplifies the received data voltage during the read operation. For achieving this, the sense amplifier 1230 may be configured to include a plurality of sense amplifier circuits to sense and amplify the data voltage. For example, each of the sense amplifier circuits may be configured to compare the data voltage with a reference voltage and output a result of the comparison as a digital-level data signal.

In FIG. 2, the write driver 1220 and the sense amplifier 1230 may be implemented with a single module. A module including the write driver 1220 and the sense amplifier 1230 may be referred to as a write and sense circuit 1235.

The I/O circuit 1240 is connected to the write and sense circuit 1235. The I/O circuit 1240 receives data from the controller 1100 (see FIG. 1) and provides read data to the controller 1100.

The decoder 1250 is connected to the memory cell array 1210 through a wordlines WL. The decoder 1250 receives an address ADDR through the controller 1100. The decoder 1250 decodes the address ADDR to select one of memory cells connected to wordlines WL and bitlines BL.

The block counter 1260 may receive a block address BLK_ADDR through the controller 1100 and manage access number to a corresponding block.

The control logic 1270 may receive a write command W_CMD or a read command R_CMD from the controller 1100. The control logic 1270 controls the overall write or read operation of the data device 1200 in response to the received write command W_CMD or the received read command R_CMD.

FIG. 3 is an exemplary detailed block diagram of the memory cell array 1210 in FIG. 2. A predetermined block BLKi of the memory cell array 1210 in FIG. 2 is shown in FIG. 3. For brevity of description, let it be assumed that the block BLKi is connected to four bitlines BL1 to BL4.

As illustrated in FIG. 3, the memory block BLKi includes a plurality of memory cells MC. Each of the memory cells MC includes a variable resistance memory VR and a cell transistor CT.

Resistance of the variable resistance memory VR varies depending on intensity and direction of provided current (or voltage). The resistance of the variable resistance memory VR is maintained as it is even when current (or voltage) is cut off. That is, the variable resistance memory VR has nonvolatile characteristics.

The variable resistance memory VR may be implemented using various elements. In some example embodiments, the variable resistance memory VR may be implemented using an STT-MRAM. In other example embodiments, the variable resistance memory VR may be implemented using a phase change RAM (PRAM) using a phase change material, a resistive RAM (ReRAM) using a variable resistive material of complex metal oxide or a magnetic RAM (MRAM) using a ferroelectric material.

A gate of the cell transistor CT is connected to a wordline WL. The cell transistor CT is switched by a signal provided through the wordline WL. A drain of the cell transistor CT is connected to the variable resistance memory VR, and a source thereof is connected to a source line SL.

In some example embodiments, sources of cell transistors CT of the memory cells MC may all be connected to the same source line. In other example embodiments, sources of cell transistors of the memory cells MC may be connected to different source lines, respectively.

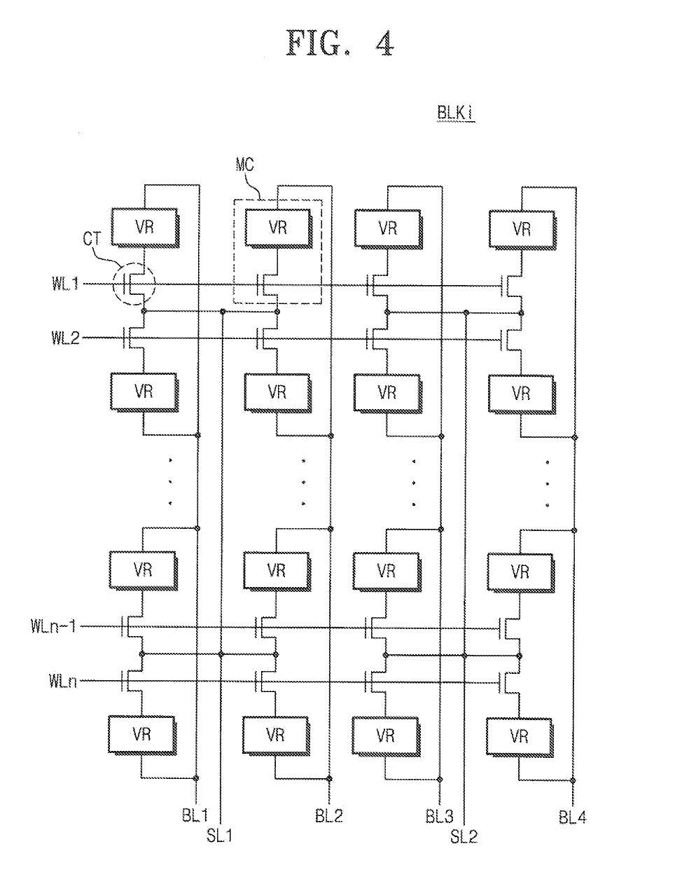

FIG. 4 is another exemplary detailed block diagram of the memory cell array 1210 in FIG. 2. As illustrated, a block BLKj of the memory cell array 1210 may be configured such that different sour memory cells MC share a single source line SL. Except for a connection manner of the source line SL, a structure of the block BLKj and the memory cell MC in FIG. 4 are similar to a structure of the block BLKi and the memory cell MC in FIG. 3 and will not be described in further detail.

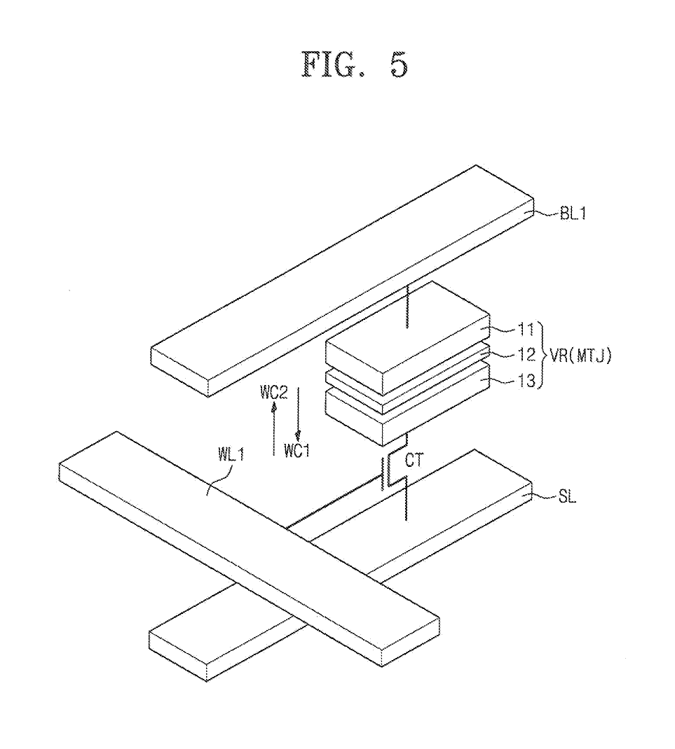

FIG. 5 is an exemplary diagram illustrating a configuration of a memory cell in a memory cell array in FIG. 2. An example of implementing a memory cell MC using an STT-MRAM is shown in FIG. 5.

As illustrated in FIG. 5, the memory cell MC may include a variable resistance memory VR and a cell transistor CT. A gate of the cell transistor CT is connected to a wordline (e.g., first wordline WL1), and one electrode of the cell transistor CT is connected to a bitline (e.g., first bitline BL1) through the variable resistance memory VR. Another electrode of the cell transistor CT is connected to a source line (e.g., first source line SL1).

The variable resistance memory VR implemented with an MTJ element may include a pinned layer 13, a free layer 11, and a tunnel layer 12 disposed therebetween. A magnetization direction of the pinned layer 13 may be fixed, and a magnetization direction of the free layer 11 may be identical or opposite to that of the pinned layer 13 according to conditions. For example, an antiferromagnetic layer (not shown) may be further provided to fix the magnetization direction of the pinned layer 13.

In order to perform a read operation of the STT-MRAM, a logic-high voltage is provided to the wordline WL1 to turn on the cell transistor CT and read current is provided from the bitline BL1 in a direction of a source line SL to detect data stored in the variable resistance memory VR according to measured resistance.

In order to perform a write operation of the STT-MRAM, a logic-high voltage is provided to the wordline WL to turn on the cell transistor CT and write current is provided between the bitline BL1 and the source line SL.

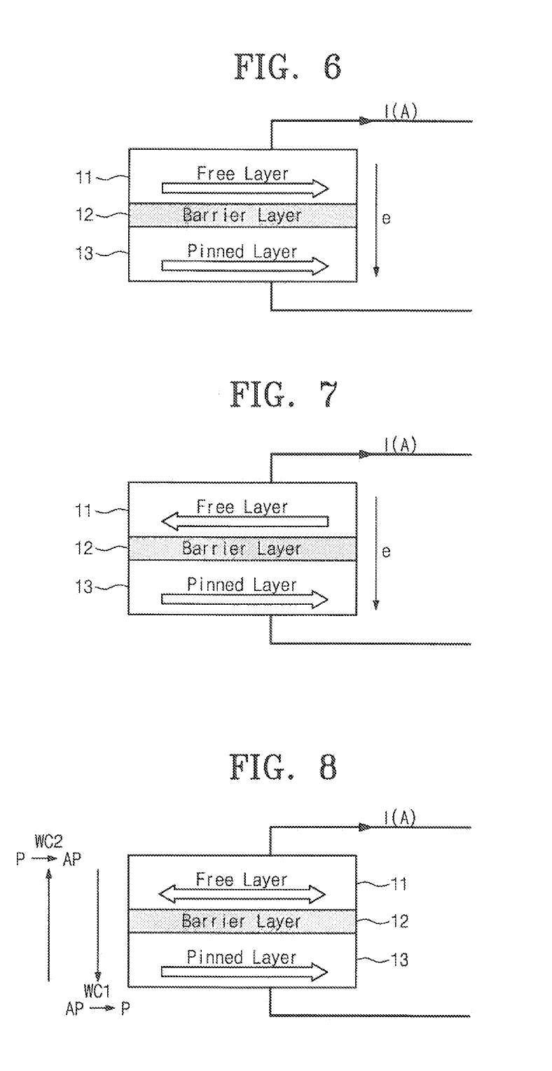

FIGS. 6 and 7 illustrate magnetization directions of a variable resistance memory VR according to stored data. Resistance of the variable resistance memory VR varies depending on a magnetization direction of the free layer 11. When the variable resistance memory VR is provided with read current I, a data voltage is output according to the resistance of the variable resistance memory VR. Since the intensity of the read current I is much lower than that of write current, the magnetization direction of the free layer 11 is not generally changed by the read current I.

Referring to FIG. 6, in the variable resistance memory VR, the magnetization direction of the free layer 11 and the magnetization direction of the pinned layer 13 are parallel to each other. Thus, the variable resistance memory VR has low resistance. In this case, data, e.g., data “0” may be read.

Referring to FIG. 7, in the variable resistance memory VR, the magnetization direction of the free layer 11 and the magnetization direction of the pinned layer 13 are antiparallel to each other. Thus, the variable resistance memory VR has high resistance. In this case, data, e.g., data “1” may be read.

In FIGS. 6 and 7, the free layer 11 and the pinned layer 13 of an MTJ cell 10 are shown as horizontal magnetic elements but are not limited thereto. In other embodiments, the free layer 11 and the pinned layer 13 may employ vertical magnetic elements.

FIG. 8 illustrates a write operation of an STT-MRAM. Referring to FIG. 8, a magnetization direction of a free layer 11 may be decided according to directions of write currents WC1 and WC2 flowing to a variable resistance memory VR. For example, when first write current WC1 is provided, free electrons having the same spin direction as a pinned layer 13 apply a torque to the free layer 11. Thus, the free layer 11 is magnetized parallel to the pinned layer 13.

On the other hand, when second write current WC2 is provided, electrons having an opposite spin to the pinned layer 13 apply a torque to the free layer 11. Thus, the free layer 11 is magnetized antiparallel to the free layer 13. That is, in the variable resistance memory VR, the magnetization direction of the free layer 11 may be changed by a spin transfer torque (STT).

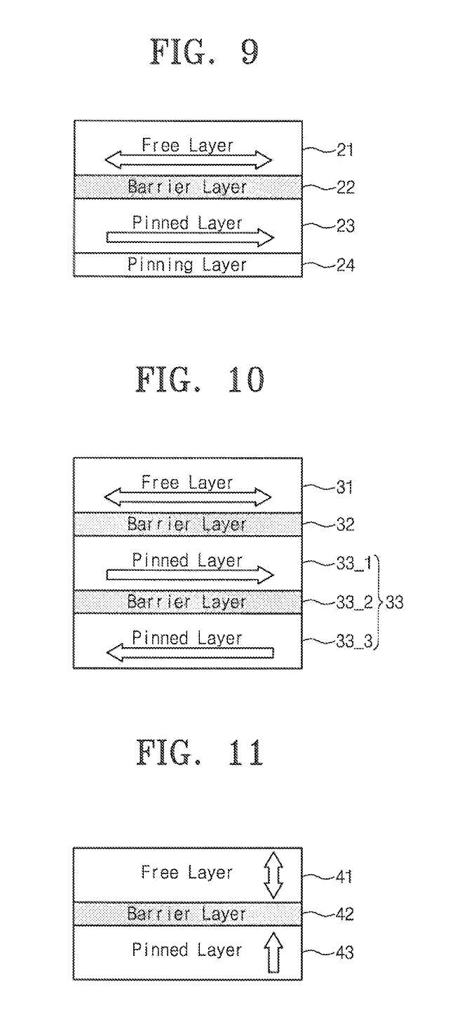

FIGS. 9 and 10 illustrate embodiments of a variable resistance memory VR in an STT-MRAM. A magnetization direction of the variable resistance memory VR is horizontal and a flow direction of current and a magnetization easy-axis are substantially vertical to each other.

Referring to FIG. 9, a variable resistance memory VR may include a free layer 21, a tunnel layer 22, a pinned layer 23, and a pinning layer 24.

The free layer 21 may include a material having a variable magnetization direction. A magnetization direction of the free layer 21 may be changed by electric/magnetic factors provided from the outside and/or inside of a memory cell.

The free layer 21 may include a ferromagnetic material including at least one of cobalt (Co), iron (Fe), and nickel (Ni). For example, the free layer 21 may include at least one selected from the group consisting of FeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

The tunnel layer 22 may have a thickness less than a spin diffusion distance. The tunnel layer 22 may include a non-magnetic material. In some embodiments, the tunnel layer 12 may include at least one selected from the group consisting of magnesium (Mg), titanium (Ti), aluminum (Al), a magnesium-zinc (MgZn) oxide, magnesium-boron (MgB) oxide, Ti nitride, and vanadium (V) nitride.

The pinned layer 23 may have a magnetization direction fixed by the pinning layer 24. The pinned layer 23 may include a ferromagnetic material. For example, the pinned layer 23 may include at least one selected from the group consisting of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

The pinning layer 24 may include antiferromagnetic material. For example, the pinning layer 24 may include at least one selected from the group consisting of PtMn, IrMn, MnO, MnS, MnTe, MnF₂, FeCl₂, FeO, CoCl₂, CoO, NiCl₂, NiO, and Cr.

In other embodiments, since a free layer and a pinned layer of the variable resistance memory VR are each made of a ferromagnetic material, a stray field may be generated at the edge of the ferromagnetic material. The stray field may reduce magnetoresistance or increase resistive magnetism of the free layer. In addition, the stray field may affect switching characteristics to result in asymmetric switching. Accordingly, there is a need for a structure to reduce or control a stray field generated at the ferromagnetic material in the variable resistance memory VR may be used.

Referring to FIG. 10, a pinned layer 33 of the variable resistance memory VR may be made of a synthetic anti-ferromagnetic (SAF) material. The pinned layer 33 may include a first ferromagnetic layer 33_1, a coupling layer 33_2, and a second ferromagnetic layer 33_3. Each of the first and second ferromagnetic layers 33_1 and 33_3 may include at least one selected from the group consisting of CoFeB, Fe, Co, Ni, Gd, Dy, CoFe, NiFe, MnAs, MnBi, MnSb, CrO₂, MnOFe₂O₃, FeOFe₂O₃, NiOFe₂O₃, CuOFe₂O₃, MgOFe₂O₃, EuO, and Y₃Fe₅O₁₂.

In this case, a magnetization direction of the first ferromagnetic layer 33_1 and a magnetization direction of the second ferromagnetic layer 33_3 are different from each other and are fixed. The coupling layer 33_2 may include ruthenium (Ru).

FIG. 11 illustrates another embodiment of a variable resistance memory in an STT-MRAM. A magnetization direction of the variable resistance memory VR is vertical and a flow direction of current and a magnetization easy-axis are substantially parallel to each other. Referring to FIG. 11, the variable resistance memory VR includes a free layer 41, a pinned layer 43, and a tunnel layer 42.

Resistance is small when a magnetization direction of the free layer 41 and a magnetization direction of the pinned layer 43 are parallel to each other and is high when the magnetization direction of the free layer 41 and the magnetization direction of the pinned layer 43 are antiparallel to each other. Data may be stored according to the resistance.

In order to implement the variable resistance memory VR having a vertical magnetization direction, each of the free layer 41 and the pinned layer 43 may be made of a material having high magnetic anisotropy energy. Examples of the material having high magnetic anisotropy energy include an amorphous rare earth element alloy, a multi-layer thin film such as (Co/Pt)n or (Fe/Pt)n, and an ordered lattice material having an L10 crystal structure.

For example, the free layer 41 may be made of an ordered alloy and may include at least one selected from the group consisting of Fe, Co, Ni, palladium (Pa), and platinum (Pt). Alternatively, the free layer 41 may include at least one selected from the group consisting of an Fe—Pt alloy, an Fe—Pd alloy, a Co—Pd alloy, a Co—Pt alloy, an Fe—Ni—Pt alloy, a Co—Fe—Pt alloy, and a Co—Ni—Pt alloy. Such alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀ or Co₃₀Ni₂₀Pt₅₀ in terms of quantitative chemistry.

The pinned layer 43 may be made of an ordered alloy and may include at least one selected from the group consisting of Fe, Co, Ni, Pa, and Pt. For example, the pinned layer 43 may include at least one selected from the group consisting of an Fe—Pt alloy, an Fe—Pd alloy, a Co—Pd alloy, a Co—Pt alloy, an Fe—Ni—Pt alloy, a Co—Fe—Pt alloy, and a Co—Ni—Pt alloy. Such alloys may be, for example, Fe₅₀Pt₅₀, Fe₅₀Pd₅₀, Co₅₀Pd₅₀, Co₅₀Pt₅₀, Fe₃₀Ni₂₀Pt₅₀, Co₃₀Fe₂₀Pt₅₀, or Co₃₀Ni₂₀Pt₅₀ in terms of quantitative chemistry.

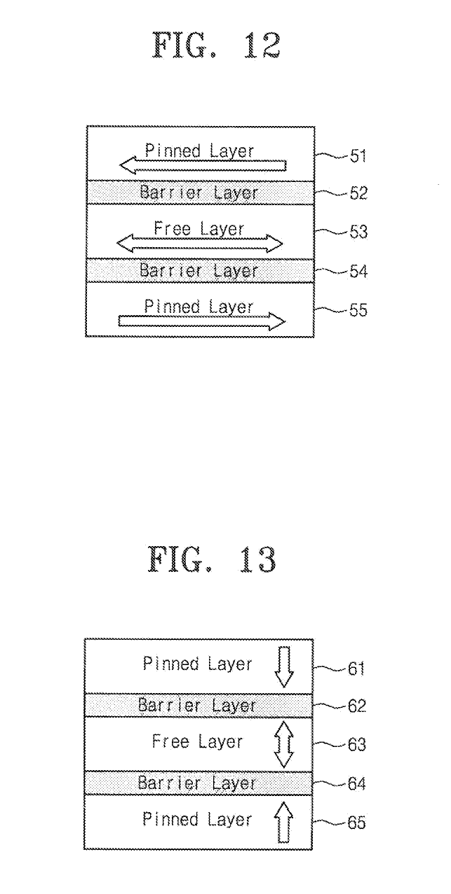

FIGS. 12 and 13 illustrate another embodiment of a variable resistance memory in an STT-MRAM. A dual variable resistance memory configured such that a tunnel layer and a pinned layer are disposed at both ends of a free layer.

Referring to FIG. 12, a dual variable resistance memory having a horizontal magnetization direction may include a first pinned layer 51, a first tunnel layer 52, a free layer 53, a second tunnel layer 54, and a second pinned layer 55. Materials of the free layer 53, the first and second tunnel layers 52 and 54, and the first and second pinned layers 51 and 55 are identical or similar to those of the free layer 21, the tunnel layer 22, and the pinned layer 23 in FIG. 9, respectively.

In this case, when a magnetization direction of the first pinned layer 51 and a magnetization direction of the second pinned layer 55 are fixed to opposite directions, magnetic forces generated by the first and second pinned layers 81 and 85 substantially counterbalance. Thus, the dual variable resistance memory may perform a write operation using smaller current than that of a typical variable resistance memory.

Since the dual variable resistance memory provides higher resistance during a read operation due to the second tunnel layer 54, an accurate data value may be obtained.

Referring to FIG. 13, a dual variable resistance memory having a vertical magnetization direction may include a first pinned layer 61, a first tunnel layer 62, a free layer 63, a second tunnel layer 64, and a second pinned layer 65. Materials of the free layer 63, the first and second tunnel layers 62 and 64, and the first and second pinned layers 61 and 65 are identical or similar to those of the free layer 41, the tunnel layer 42, and the pinned layer 43 in FIG. 11, respectively.

In this case, when a magnetization direction of the first pinned layer 91 and a magnetization direction of the second pinned layer 65 are fixed to opposite directions, magnetic forces generated by the first and second pinned layers 61 and 65 substantially counterbalance. Thus, the dual variable resistance memory may perform a write operation using smaller current than that of a typical variable resistance memory.

As described with reference to FIGS. 6 to 13, the memory device 1200 (see FIG. 2) according to an embodiment of the inventive concept may use a variable resistance memory VR as a storage device. Mechanism of a read operation on the variable resistance memory VR is similar to that of a write operation. That is, as described with reference to FIGS. 6 to 8, mechanism of a read operation and mechanism of a write operation are similar to each other except that intensities of read current and write current are different from each other.

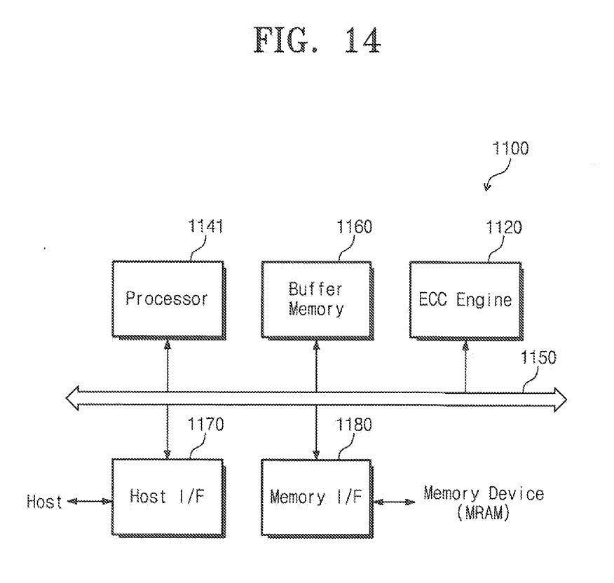

FIG. 14 is a detailed block diagram illustrating an exemplary configuration of the controller 1100 in FIG. 1. As illustrated, the controller 1100 may include a processor 1141, a buffer memory 1160, an ECC engine 1120, a system bus 1150, a host interface 1170, and a memory interface 1180.

The processor 1141 may control the overall operation of the controller 1100 and serve as a rewrite managing unit 1140 (see FIG. 1) implemented by firmware or software.

The system bus 1150 provides a channel between the processor 1141, the buffer memory 1160, the ECC engine 1120, the host interface 1170, and the memory interface 1180.

The host interface 1170 may communicate with a host via a specific communication standard. For example, the host interface 1170 may communicate with the host via at least one of various communications standards such as USB (Universal Serial Bus), MMC (multimedia card), PCI (peripheral component interconnection), PCI-E (PCI-express), ATA (Advanced Technology Attachment), Serial-ATA, Parallel-ATA, SCSI (small computer small interface), ESDI (enhanced small disk interface), IDE (Integrated Drive Electronics), and a Firewire.

The processor 1141 may receive host data and a command from the host to control the overall operation of the memory controller 1100.

The buffer memory 1160 may be implemented with an SRAM, a DRAM or an MRAM and may be used as at least one of a working memory, a cache memory, and a buffer memory of the controller 1100.

The ECC engine 1120 may perform error correction coding on data received from the host or data received from the memory device 1200 through an error correction coding algorithm. ECC encoding and ECC decoding operations may be called an ECC operation. The ECC engine 1120 may restore one or two bits of error to original data through the error correction coding algorithm.

The memory interface 1180 interfaces with the memory device 1200. For example, when the memory device 1200 is a resistive memory, the memory interface 1180 may include a DRAM interface or the like.

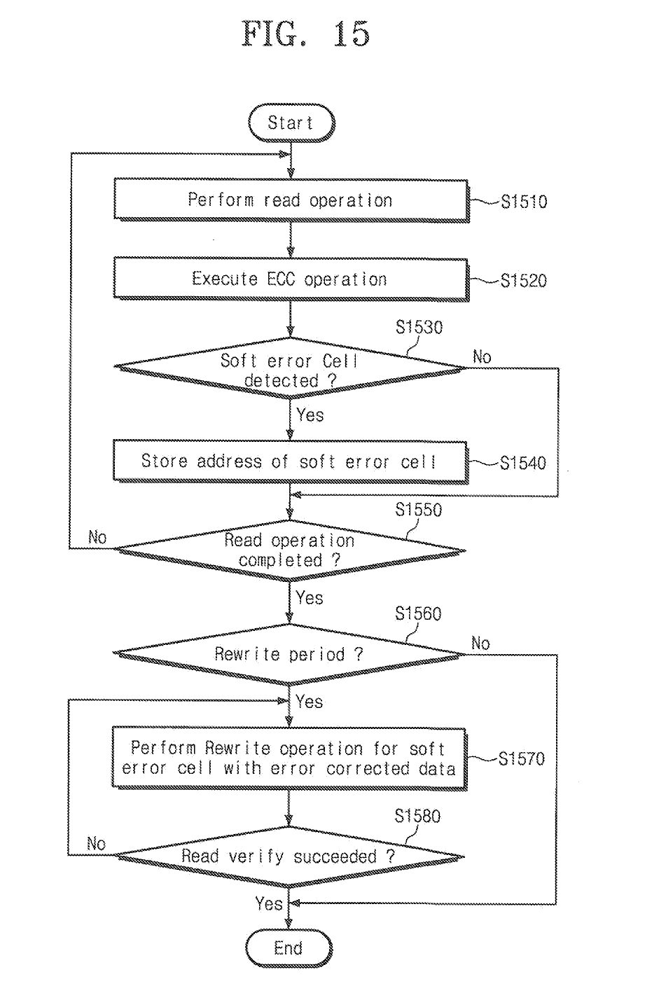

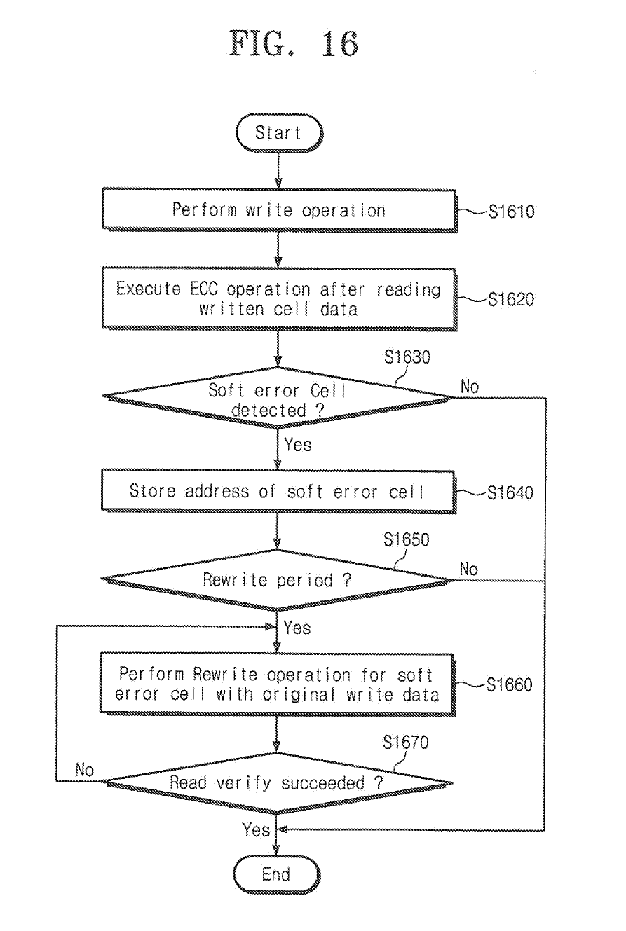

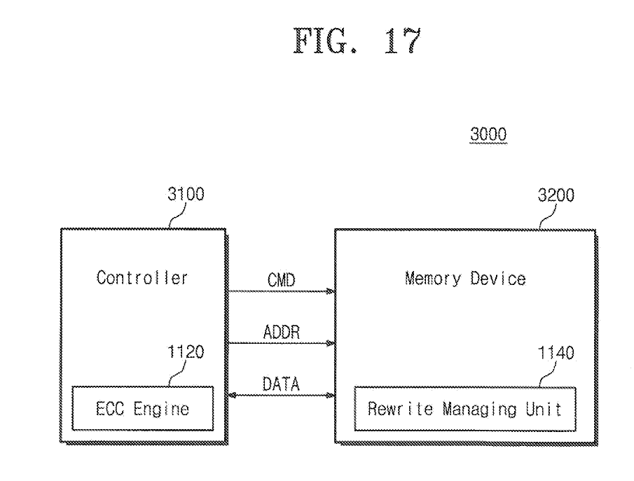

FIG. 15 is a rewrite control flowchart during a read operation.

In case of a read operation, the memory system 1000 performs a read operation and executes an ECC operation (S1510 and S1520).

The system 1000 detects whether there is a soft error cell in the memory cells from which data was read (S1530). The detection operation occurs when the ECC engine 1220 performs error correction code (ECC) processing on data read from resistive memory cells. When a soft error cell is detected, an address of the soft error cell is stored (S1540). In some cases, the address of the soft error cell may be stored in the buffer memory 1160 in FIG. 14. In addition, in some embodiments, error corrected data for the soft error cell generated by the ECC processing may be stored in the buffer memory along with the address of the soft error cell.

The memory system 1000 then checks to see if the entire read operation has completed (S1550).

When the read operation is complete, the system checks to see if it is currently in a rewrite period (S1560). As noted above, the system 1000 may not always perform a rewrite operation after every read operation, but may only perform the rewrite operation if the system is in a rewrite period, which may occur at regular intervals, such as once per second. If the system is in a rewrite period the flow proceeds to S1570.

At block S1570, the memory system 1000 selectively rewrites error-corrected data into a soft error cell corresponding to the stored address. In this case, the rewritten data may be error-corrected data that is obtained during the ECC processing. For example, when data “1” is read and determined to be an error, data “0” is written into a corresponding soft error cell. On the other hand, when data “0” is read and determined to be an error, data “1” is written into a corresponding soft error cell.

The rewrite operation is identical or similar to the above-described write operation and will not be described in further detail.

After the rewrite operation is completed, a read verify operation may be additionally performed. In this case, the ECC engine 1120 may check to see whether the rewrite operation was successfully performed (S1580).

In case of a resistive memory, the read current applied to a memory cell to read data from the memory cell is smaller than write current needed to write data to the memory cell. However, there is probability that data can be written into the memory cell by the relatively smaller read current. That is, the smaller read current can cause the programmed state of the memory cell to change from a ‘0’ to a ‘1’, or vice-versa. One of the ways to reduce a read error rate is to increase thermal barrier of a magnetic tunnel junction (MTJ) element constituting a memory cell of a resistive memory. However, increasing the thermal barrier of the MTJ may cause the write current needed to write data to the cell to increase, which increases power consumption during the write operation. Since a soft error cell may be caused by a read current, characteristics of a raw bit error rate that the memory cell itself must have may be relaxed when the read error rate is reduced through a rewrite operation described in FIG. 15.

For example, assuming that a rewrite operation is executed every second after ECC processing is performed and ten-year reliability is guaranteed, a raw bit error rate may reduced more significantly than when only ECC processing is performed and a rewrite operation is not executed. As a result, the thermal barrier of a memory cell can be reduced.

FIG. 16 is a write control flowchart during a write operation.

In case of a write operation, the memory system 1000 performs a write operation (S1610). While the write operation is performed or after the write operation is completed, the memory system 1000 may execute ECC operation by reading data from a memory cell to check whether data is normally written (S1620).

Detection is made on whether there is a soft error cell (S1630). When the soft error cell is detected, an address of the soft error cell is stored (S1640). In this case, the address of the soft error cell may be stored in the buffer memory 1160 in FIG. 14.

The memory system 1000 checks whether a period is a rewrite period (S1650).

When the period is the rewrite period, the flow proceeds to S1660.

The memory system 1000 selectively rewrites data into a soft error cell corresponding to the stored address (S1660). In this case, rewritten data is error-corrected data or original write data. For example, when data “1” is read and determined to be an error, data “0” is written into a corresponding soft error cell. On the other hand, when data “0” is read and determined to be an error, data “1” is written into a corresponding soft error cell. The rewrite operation is identical or similar to the above-described write operation and will not be described in further detail. The intensity of rewrite current applied during the rewrite operation may be equal to or lower than that of write current.

After the rewrite operation is completed, a read verify operation may be additionally performed. In this case, the ECC engine 1120 may check whether the read verify operation is successfully performed.

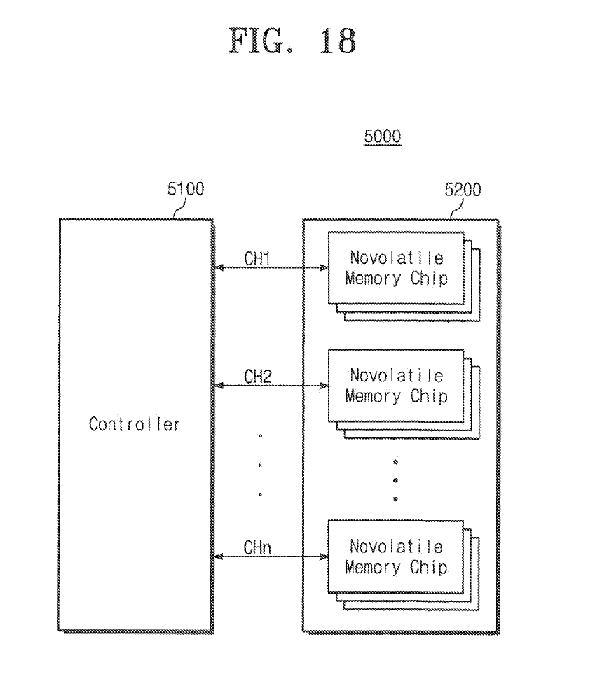

FIG. 17 is a block diagram of a memory system 3000 according to another embodiment of the inventive concept. As illustrated, the memory system 3000 includes a controller 3100 and a memory device 3200. The memory controller 3100 includes an ECC engine 1120. The memory device 3200 may include a rewrite managing unit 1140.

The controller 3100 may provide a command CMD, an address ADDR, and data DATA to the memory device 3200 to control read and write operations on the memory device 3200 in response to a request of a host.

The controller 3100 may be implemented in the same or similar manner as described in FIG. 14.

The memory device 3200 may be implemented in the same or similar manner as described in FIGS. 2 to 4.

Unlike FIG. 1, the rewrite managing unit 1140 is included in the memory device 3200 in FIG. 17. In this case, the rewrite managing unit 1140 may be implemented by the control logic 1270 in FIG. 2.

Even in the case of FIG. 17, since rewrite is performed on a soft error cell as described above, characteristics of a read error rate that a memory cell requires are relaxed. Thus, a raw bit error rate of a nonvolatile memory device is improved to guarantee reliability of a memory system including a resistive memory.

FIG. 18 is a block diagram of a nonvolatile memory system 500 with a multi-channels structure according to another embodiment of the inventive concept.

For brevity of description, a memory device described with reference to FIG. 2 was assumed to use a single nonvolatile memory chip. However, this was merely exemplary. As shown in FIG. 18, the present inventive concepts may be applied even when a plurality of nonvolatile memory chips are used.

As illustrated in FIG. 18, the nonvolatile memory system 5000 includes a controller 5100 and a memory device 5200. The memory device 5200 includes a plurality of nonvolatile memory chips each being divided into a plurality of groups.

Each group of the nonvolatile memory chips may be configured to communicate with the controller 5100 through a single common channel. As shown in FIG. 18, the nonvolatile memory chips communicate with the controller 5100 through first to n^{th} channels CH1 to CHn. Each of the nonvolatile memory chips may have the same or similar configuration as described with reference to FIG. 2 to 13. The controller 5100 may have the same or similar configuration as described with reference to FIG. 14.

In the case of FIG. 18, rewrite is performed on a soft error cell, as described above. Thus, a raw bit error rate of a nonvolatile memory is improved to guarantee reliability of a memory system including a resistive memory.

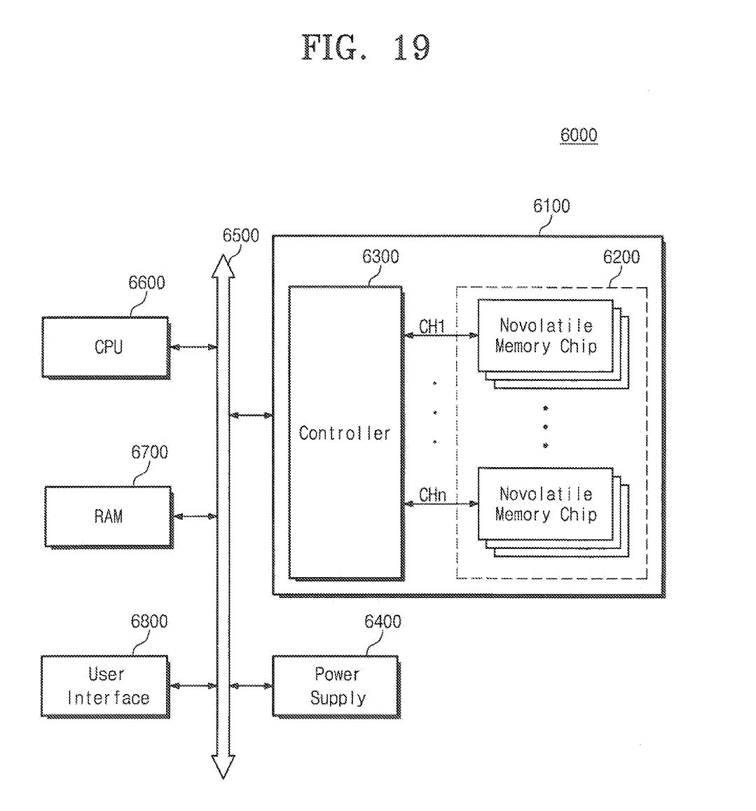

FIG. 19 is a block diagram of an electronic device 6000 including the nonvolatile memory system in FIG. 18. As illustrated, the electronic device 6000 may include a central processing unit (CPU) 6600, a random access memory (RAM) 6700, a user interface 6800, a power supply 6400, and a memory system 6100.

The memory system 6100 may be electrically connected to the CPU 6600, the RAM 6700, the user interface 6800, and the power supply 6400 through a system bus 6500. Data provided through the user interface 6800 or data processed by the CPU 6600 is stored in the memory system 6100. The memory system 6100 includes a controller 6300 and a nonvolatile memory device 6200.

In case of FIG. 19, since rewrite is performed on a soft error cell created in the nonvolatile memory device 6200, characteristics of a read error rate that a memory cell requires are relaxed to reduce a raw bit error rate of the nonvolatile memory device 6200. Thus, reliability of an electronic device including an MRAM is improved.

The electronic device 6000 may be provided as one of various elements constituting an electronic device such as a computer, an ultra-mobile PC (UMPC), a workstation, a net-book, a personal digital assistant (PDA), a portable computer, a web tablet, a wireless phone, a mobile phone, a smart phone, an e-book, a portable multimedia player (PMP), a portable game device, a navigation device, a black box, a digital camera, a digital multimedia broadcasting (DMB) player, a three-dimensional television, a smart television, a digital audio recorder, a digital audio player, a digital picture recorder, a digital picture player, a digital video recorder, and a digital video player, a device capable of transmitting/receiving information in wireless environment, one of various electronic devices constituting a home network, an RFID device or one of various elements constituting a computing system.

While the present disclosure has been particularly shown and described with reference to exemplary embodiments thereof, the general inventive concept is not limited to the above-described embodiments. It will be understood by those of ordinary skill in the art that various changes and variations in form and details may be made therein without departing from the spirit and scope of the inventive concept as defined by the following claims.

What is claimed is:

1. A method of operating a nonvolatile memory device in a memory system, comprising:
performing error correction code (ECC) processing on data read from resistive memory cells to detect whether the resistive memory cells include a soft error cell that experiences a soft error and to generate error-corrected data for the soft error cell;
storing an address of the soft error cell in response to detecting the soft error cell; and
selectively rewriting the error-corrected data into the soft error cell corresponding to the stored address.

2. The method of claim 1, wherein the resistive memory cells comprise MRAM cells.

3. The method of claim 2, wherein each of the MRAM cells includes a magnetic tunnel junction (MTJ) element.

4. The method of claim 1, wherein the soft error cell is an error cell created by a read current.

5. The method of claim 1, further comprising determining if the memory system is in a rewrite period, wherein the write is performed in response to determining that the system is in the rewrite period.

6. The method of claim 1, wherein the error correction code (ECC) processing is performed to correct one bit of error.

7. The method of claim 1, further comprising:
performing a read verify operation to verify whether the rewrite is successfully performed.

8. The method of claim 1, wherein selectively rewriting the error-corrected data is performed in response to a raw bit error rate of the resistive memory cells exceeding a predetermined bit error rate.

9. The method of claim 1, wherein the nonvolatile memory device is mounted in a timing controller as a data storage device.

10. The method of claim 9, wherein the timing controller controls a display circuit block in a display device.

11. The method of claim 1, further comprising:
checking completion of a read operation after storing the address of the soft error cell;
wherein selectively rewriting the error-corrected data is performed after the read operation has completed.

12. A method of operating a nonvolatile memory device, comprising:
writing data into resistive memory cells;
reading the data written into the resistive memory cells after writing the data into the resistive memory cells;
performing error correction code (ECC) processing on data read from the read data to detect whether there is a soft error cell and to generate error-corrected data for the soft error cell; and
selectively rewriting the error-corrected data into the soft error cell.

13. The method of claim 12, wherein the resistive memory cells are STT-MRAM cells.

14. The method of claim 13, wherein each of the STT-MRAM cells includes a magnetic tunnel junction (MTJ) element and a cell transistor.

15. The method of claim 12, wherein the soft error cell is created by a write error rate.

16. The method of claim 12, further comprising determining if the system is in a rewrite period, wherein the rewrite is performed in response to determining that the system is in the rewrite period.

17. A method of operating a nonvolatile memory device, comprising:
reading data from a resistive memory cell;
performing error correction code (ECC) processing on data read from resistive memory cells to detect whether the resistive memory cells include a soft error cell that experiences a soft error; storing an address of the soft error cell in response to detecting the soft error cell;
generating error-corrected data corresponding to the soft error cell; and
selectively rewriting the error-corrected data into the soft error cell corresponding to the stored address.

18. The method of claim 17, further comprising determining if the system is in a rewrite period, wherein the write is performed in response to determining that the system is in the rewrite period.

19. The method of claim 17, further comprising:
checking completion of a read operation after storing the address of the soft error cell;
wherein selectively rewriting the error-corrected data is performed after the read operation has completed.

20. The method of claim 17, wherein selectively rewriting the error-corrected data is performed in response to a raw bit error rate of the resistive memory cells exceeding a predetermined bit error rate.
